(19) United States
(12) Patent Application Publication
(10) Pub. No.: US 2009/0057750 A1
(43) Pub. Date: Mar. 5, 2009

(54) NONVOLATILE SEMICONDUCTOR MEMORY ELEMENT AND MANUFACTURING METHOD THEREOF

(76) Inventors: Akira TAKASHIMA, Fuchu-shi (JP); Shoko Kikuchi, Kawasaki-shi (JP); Koichi Muraoka, Sagamihara-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/049,875

(22) Filed: Mar. 17, 2008

(30) Foreign Application Priority Data
Aug. 29, 2007 (JP) 2007-222690

(51) Int. Cl. H01L 29/00

(52) U.S. Cl. 257/321; 438/594; 257/E29.001; 257/E21.294

(57) ABSTRACT

A nonvolatile semiconductor memory element includes a semiconductor substrate, a source region and a drain region which are provided separately in the semiconductor substrate, a tunnel insulating layer which is provided between the source region and the drain region on the semiconductor substrate, a charge storage layer which is provided on the tunnel insulating layer, a block insulating layer which is provided on the charge storage layer and includes a crystallized lanthanum aluminate layer, and a control gate electrode which is provided on the block insulating layer.

### CROSS-REFERENCE TO RELATED APPLICATIONS

This application is based upon and claims the benefit of priority from prior Japanese Patent Application No. 2007-222690, filed Aug. 29, 2007, the entire contents of which are incorporated herein by reference.

### BACKGROUND OF THE INVENTION

1. Field of the Invention

The present invention relates to a nonvolatile semiconductor memory element and a manufacturing method thereof, and, for example, to a nonvolatile semiconductor memory element which stores information by injecting or releasing a charge into or from a charge storage layer.

2. Description of the Related Art

A memory cell transistor in a flash memory or a MONOS (Metal Oxide Nitride Oxide Semiconductor) nonvolatile semiconductor memory device has a gate structure in which a tunnel insulating layer, a charge storage layer, a block insulating layer, and a control gate electrode are stacked on a semiconductor substrate. Data is written to or erased from the memory cell transistor by applying a voltage to the control gate electrode and injecting charge from the semiconductor substrate into the charge storage layer or releasing charge from the charge storage layer.

To make the memory larger in capacity and faster in speed, miniaturization of the memory cell transistors and peripheral circuits is required. Since the transistors, the major elements of the peripheral circuits, are also miniaturized and the withstand voltage of them drops, it is necessary to lower the write voltage or erase voltage applied to the control gate electrode of the memory cell transistor. Moreover, to achieve higher speed, it is necessary to inject charge from the semiconductor substrate efficiently into the charge storage layer via the tunnel insulating film or release charge from the storage charge layer efficiently. Therefore, to realize a high-speed and high-capacity, it is necessary to inject or release charge into or from the charge storage layer efficiently at a low voltage.

To satisfy this requirement, the following two points can be considered. First, the tunnel insulating layer can be formed into a thin film, thereby making it easier to inject or release charge. However, since forming the tunnel insulating film into a thin film degrades the charge retention characteristic, there is a limit to forming the tunnel insulating layer into a thin film. Second, to increase the electric field applied to the tunnel insulating layer, the capacitance of the block insulating film can be increased. To increase the capacitance of the block insulating film, the following can be considered: (1) forming the block insulating film into a thin film; (2) increasing the contact area of the block insulating layer with the charge storage layer; and (3) using a high-dielectric material for the block insulating layer. However, in item (1), there is a limit to thin-film formation, taking into account the degradation of the charge retention characteristic of the charge storage layer. In item (2), the top face and side face of the charge storage layer have to be covered with the block insulating layer, which makes the miniaturization difficult. In item (3), the electrical film thickness of the block insulating layer can be decreased, while the physical film thickness is kept unchanged. Moreover, since the capacitance of the block insulating film can be increased without increasing the contact area of the block insulating layer with the charge storage layer, it is easier to miniaturize the memory cell transistors. Therefore, the development of the application of a high-dielectric material to the block insulating film is in progress.

To apply a high-dielectric material to the block insulating layer, it is desirable that the block insulating layer be applicable to a method of forming a conventional memory cell transistor. A method of forming a conventional flash memory or MONOS memory cell transistor is to form a gate structure which has a tunnel insulating layer, a charge storage layer, a block insulating layer, and a control gate electrode deposited in that order on a semiconductor substrate. Then, impurities, such as boron (B), phosphorus (P), arsenic (As), or antimony (Sb), are ion-implanted into the semiconductor substrate, thereby forming ion-implanted regions. Finally, the sample is heat-treated, thereby activating the ion-implanted regions.

As described above, in the conventional forming method, since the ion-implanted regions are activated after the gate structure is formed, the gate structure is heated at a high temperature. In that case, the reaction of the block insulating layer with the control gate electrode and charge storage layer arranged on and under the block insulating layer respectively is a problem. For example, in a case where polysilicon is used for the charge storage layer and hafnium oxide is used for the block insulating layer, when the heat treatment is performed as described above, a low-dielectric oxidative reaction layer is formed between the polysilicon and the hafnium oxide, causing a problem: the interface structure changes its nature. Consequently, the characteristics of the charge storage layer, block insulating layer, and control gate electrode deteriorate as a result of a decrease in the capacitance due to the series capacitance of the block insulating layer and the oxidative reaction layer or an increase in the leakage current caused by the modulation of the work function of the upper and lower electrodes. Eventually, the characteristics of the memory cell transistor deteriorate.

As for related techniques of this type, a semiconductor memory element has been disclosed which uses a high-dielectric material capable of preventing unexpected crystallization even when a heat treatment is performed at a high temperature in manufacturing semiconductor memory elements (refer to JPA 2006-203200 (KOKAI)).

### BRIEF SUMMARY OF THE INVENTION

According to an aspect of the present invention, there is provided a nonvolatile semiconductor memory element comprising: a semiconductor substrate; a source region and a drain region which are provided separately in the semiconductor substrate; a tunnel insulating layer which is provided between the source region and the drain region on the semiconductor substrate; a charge storage layer which is provided on the tunnel insulating layer; a block insulating layer which is provided on the charge storage layer and includes a crystallized lanthanum aluminate layer; and a control gate electrode which is provided on the block insulating layer.

According to an aspect of the present invention, there is provided a method of manufacturing a nonvolatile semiconductor memory element, comprising: forming a tunnel insulating layer on a semiconductor substrate; forming a charge storage layer on the tunnel insulating layer; forming, on the charge storage layer, a block insulating layer including a lanthanum aluminate layer; forming a control gate electrode on the block insulating layer; introducing impurities in the semiconductor substrate to form a first impurity region and a second impurity region in the semiconductor substrate; and performing a heat treatment to crystallize the lanthanum aluminate layer.

### BRIEF DESCRIPTION OF THE SEVERAL VIEWS OF THE DRAWING

FIG. 1 is a sectional view illustrating a memory cell transistor according to a first embodiment;

FIG. 2 is a sectional view illustrating the process of manufacturing a memory cell transistor according to the first embodiment;

FIG. 3 is a sectional view illustrating the process of manufacturing a memory cell transistor following FIG. 2;

FIG. 4 is a sectional view illustrating the process of manufacturing a memory cell transistor following FIG. 3;

FIG. 5 is a sectional view illustrating the process of manufacturing a memory cell transistor following FIG. 4;

FIG. 6 is an electron diffraction image of a crystallized lanthanum aluminate layer 14;

FIG. 7 is a diagram illustrating a leakage current in a gate structure including an amorphous lanthanum aluminate layer and that in a gate structure including a crystallized lanthanum aluminate layer;

FIG. 8 is a diagram illustrating a leakage current in a gate structure including an amorphous lanthanum aluminate layer and that in a gate structure including a crystallized lanthanum aluminate layer in a case where the ratio of lanthanum to aluminum is 1:4;

FIG. 9 is a sectional view illustrating a memory cell transistor according to a second embodiment;

FIG. 10 is a sectional view illustrating the process of manufacturing a memory cell transistor according to the second embodiment;

FIG. 11 is a sectional view illustrating the process of manufacturing a memory cell transistor following FIG. 10;

FIG. 12 is a sectional view illustrating the process of manufacturing a memory cell transistor following FIG. 11;

FIG. 13 is a sectional view illustrating the process of manufacturing a memory cell transistor following FIG. 12;

FIG. 14 is a sectional view illustrating the process of manufacturing a memory cell transistor following FIG. 13;

FIG. 15 is a diagram illustrating a stacked structure of an aluminum oxide layer 14A and a lanthanum aluminate layer 14B;

FIG. 16 is a sectional view illustrating a memory cell transistor according to a third embodiment;

FIG. 17 is a sectional view illustrating the process of manufacturing a memory cell transistor according to the third embodiment;

FIG. 18 is a sectional view illustrating the process of manufacturing a memory cell transistor following FIG. 17;

FIG. 19 is a sectional view illustrating the process of manufacturing a memory cell transistor following FIG. 18;

FIG. 20 is a sectional view illustrating the process of manufacturing a memory cell transistor following FIG. 19;

FIG. 21 is a sectional view illustrating the process of manufacturing a memory cell transistor following FIG. 20;

FIG. 22 is a sectional view illustrating the process of manufacturing a memory cell transistor following FIG. 21; and

FIG. 23 is a sectional view illustrating a memory cell transistor according to a fourth embodiment.

### DETAILED DESCRIPTION OF THE INVENTION

Hereinafter, referring to the accompanying drawings, embodiments of the invention will be explained. In the explanation below, elements which have the same function and configuration are indicated by the same reference numerals. A repeated explanation of them will be given only when necessary.

### First Embodiment

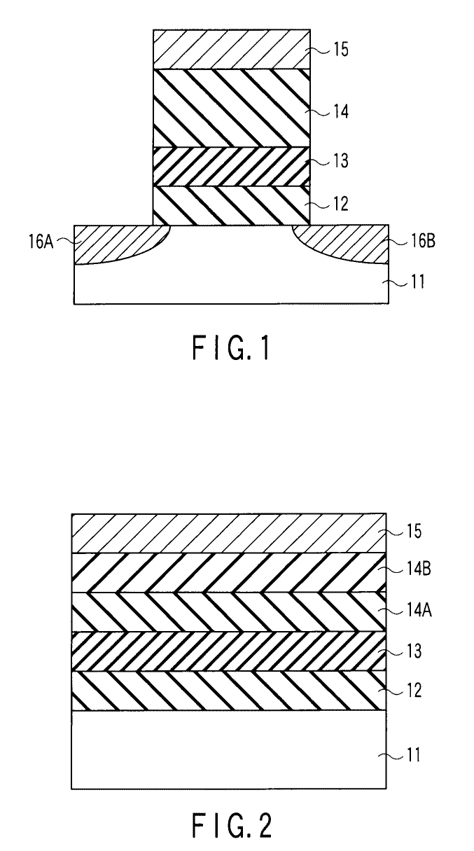

FIG. 1 is a sectional view illustrating a memory cell transistor (a nonvolatile semiconductor memory element) according to the first embodiment.

A p-type-conductivity substrate 11 is, for example, a p-type semiconductor substrate, a semiconductor substrate with a p-well, or an SOI (Silicon On Insulator) substrate with a p-type semiconductor layer. A semiconductor made of silicon (Si) or the like, or a compound semiconductor made of SiGe, GaAs, ZnSe, or the like is used as the semiconductor substrate 11.

In the semiconductor substrate 11, a source region 16A and a drain region 16B are provided separately. Each of the source region 16A and drain region 16B is composed of an n⁺-type diffused region formed by introducing highly-concentrated n⁺-type impurities (such as phosphorus (P) or arsenic (As)) into silicon.

On the semiconductor substrate 11 between the source region 16A and drain region 16B (that is, on the channel region), there is provided a gate structure in which a tunnel insulating layer 12, a charge storage layer 13, a block insulating layer 14, and a control gate 15 are stacked one on top of another in that order. The block insulating layer 14 has a function of blocking a flow of electrons between the charge storage layer 13 and the control gate 15.

The memory cell transistor of the first embodiment may be of the floating gate type using a conductive material as the charge storage layer 13 or the MONOS (Metal Oxide Nitride Oxide Semiconductor) type using an insulator, such as a nitride film, as the charge storage layer 13. In FIG. 1, a MONOS memory cell transistor is shown as an example.

A MONOS memory cell transistor captures charges (electrons) and stores them in the charge storage layer 13. This charge capture capability can be expressed by the charge trap density. A higher charge trap density means that more charges can be captured.

Into the charge storage layer 13, electrons are injected from the channel region, and become captured in a trap of the charge storage layer 13. The electrons captured in the trap cannot escape easily from the trap and gradually become stable. Since the threshold voltage of the memory cell transistor changes according to the charge amount of the charge storage layer 13, data “0” and data “1” are distinguished by the level of the threshold voltage, thereby storing the data into the memory cell transistor.

An oxide or oxynitride including at least one of silicon (Si), aluminum (Al), titanium (Ti), zirconium (Zr), and hafnium (Hf) is used as the charge storage layer 13 used in the MONOS memory cell transistor.

As the charge storage layer (floating gate electrode) 13 used in a floating-gate memory cell transistor, a p⁺-type polysilicon or metallic conductive material can be used. The metallic conductive material is, for example, a single element, silicide, boride, nitride, or carbide including one or more elements selected from a group of gold (Au), platinum (Pt), cobalt (Co), beryllium (Be), nickel (Ni), rhodium (Rh), palladium (Pd), tellurium (Te), rhenium (Re), molybdenum (Mo), aluminum (Al), hafnium (Hf), tantalum (Ta), manganese (Mn), zinc (Zn), zirconium (Zr), indium (In), bismuth (Bi), ruthenium (Ru), tungsten (W), iridium (Ir), erbium (Er), lanthanum (La), titanium (Ti), and yttrium (Y).

As the tunnel insulating layer 12, silicon oxide, silicon nitride, silicon oxynitride, or the like is used.

As a material applicable to the control gate electrode 15, a p⁺-type polysilicon or metallic conductive material can be used. The metallic conductive material is, for example, a single element, silicide, boride, nitride, or carbide including one or more elements selected from a group of gold (Au), platinum (Pt), cobalt (Co), beryllium (Be), nickel (Ni), rhodium (Rh), palladium (Pd), tellurium (Te), rhenium (Re), molybdenum (Mo), aluminum (Al), hafnium (Hf), tantalum (Ta), manganese (Mn), zinc (Zn), zirconium (Zr), indium (In), bismuth (Bi), ruthenium (Ru), tungsten (W), iridium (Ir), erbium (Er), lanthanum (La), titanium (Ti), and yttrium (Y). A metallic conductive material with a large work function is particularly preferable since the leakage current from the interelectrode insulating film to the control gate electrode can be reduced and the effective oxide thickness (EOT) can be made thinner than that of a control gate electrode made of polysilicon because the metallic conductive material has no depletion layer.

In the first embodiment, crystallized lanthanum aluminate (LAO: LaAlO₃) is used as the block insulating film 14. Lanthanum aluminate (LAO) becomes stable as a result of crystallization and its insulation quality deteriorates less than that of amorphous lanthanum aluminate. Use of the crystallized lanthanum aluminate as the block insulating layer 14 prevents the layer 14 from reacting with the charge storage layer 13 or control gate electrode 15. As a result, it is possible to prevent the characteristics of the block insulating layer 14, charge storage layer 13, and control gate electrode 15 from deteriorating.

Since lanthanum aluminate is a high-dielectric material, the capacitance between the substrate 11 and the control gate electrode 15 can be made higher. This makes it possible to decrease the operating voltage applied to the control gate electrode 15.

Specifically, increasing the capacitance of the block insulating layer 14 enables an electric field applied to the tunnel insulating layer 12 to increase. This makes it possible to inject or release charge into or from the charge storage layer efficiently at a low voltage.

The coupling ratio of the capacitance between the control gate electrode 15 and the charge storage layer 13 to the capacitance between the substrate 11 and the charge storage layer 13 is expressed as C2/(C1+C2). Since a high-dielectric material is used for the block insulating layer 14 between the control gate electrode 15 and the charge storage layer 13, the capacitance C2 can be increased. This makes it possible to improve the coupling ratio of the memory cell transistor. As a result of the improvement in the coupling ratio, the element characteristics of the memory cell transistor can be improved. Moreover, increasing the capacitance C2 enables the operating voltage applied to the control gate electrode 15 to be decreased.

Next, referring to the accompanying drawings, a method of manufacturing a memory cell transistor of the first embodiment will be explained.

As shown in FIG. 2, on a p-type silicon substrate 11, a silicon oxide film 12 with a film thickness of about 5 nm is formed as a tunnel insulating layer using, for example, a thermal oxidation method. Then, on the silicon oxide layer 12, a silicon nitride layer 13 with a film thickness of about 5 nm is formed as a charge storage layer using, for example, CVD (Chemical Vapor Deposition) method.

Next, on the silicon nitride layer 13, an aluminum oxide layer 14A with a film thickness of about 10 nm and a lanthanum aluminate layer 14B with a film thickness of about 10 nm are formed as a block insulating layer in that order by, for example, MBE (Molecular Beam Epitaxy) method. The reason why the aluminum oxide layer 14A and lanthanum aluminate layer 14B are stacked as a block insulating layer is that the aluminum oxide layer 14A is caused to suppress the reaction of the lanthanum aluminate layer 14B with the underlying silicon nitride 13 when a heat treatment is performed at about 900° C. Then, on the lanthanum aluminate layer 14B, a tantalum nitride layer with a film thickness of about 5 nm is formed as a control gate electrode using, for example, sputtering method.

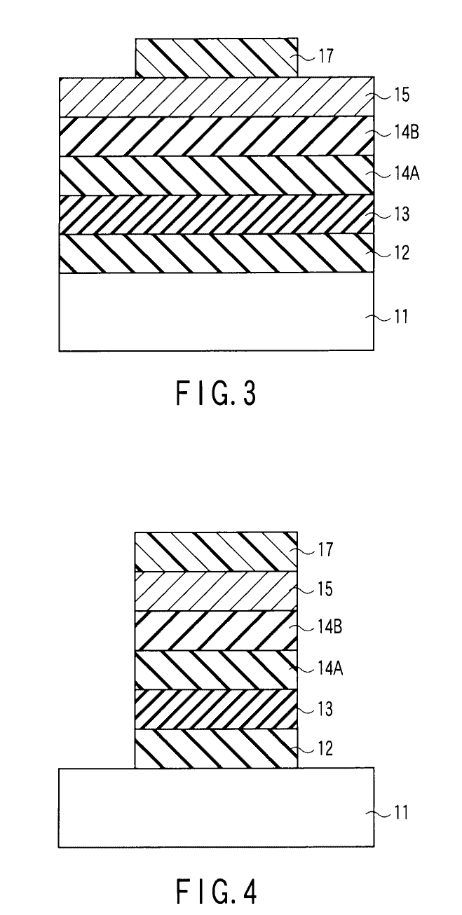

Next, as shown in FIG. 3, to form a gate structure having a desired planar shape, a resist layer 17 is formed on the tantalum nitride layer 15 using lithographic method. Then, as shown in FIG. 4, with the resist layer 17 as a mask, the gate structure is etched using RIE (Reactive Ion Etching) method, thereby exposing the top surface of the silicon substrate 11.

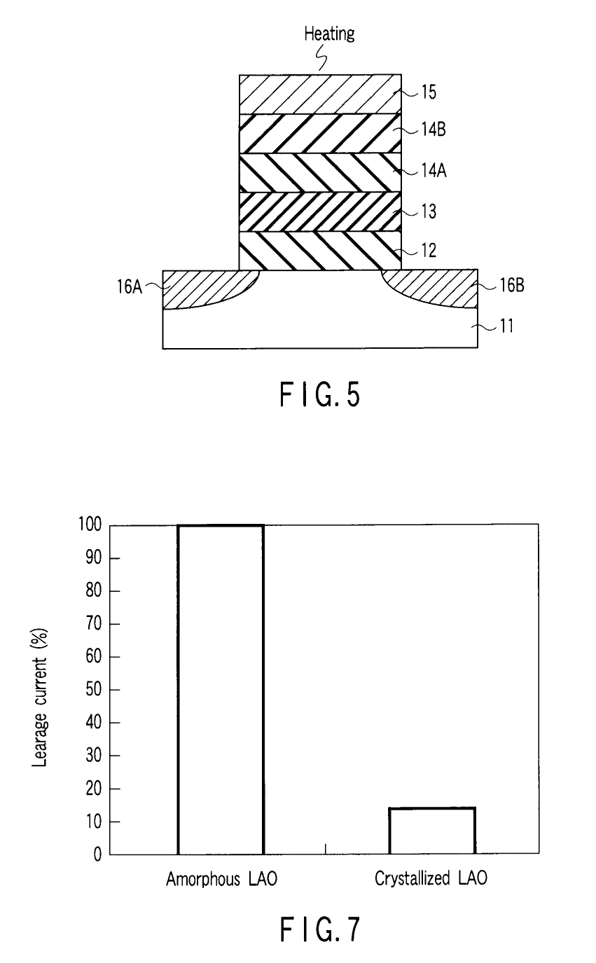

Next, as shown in FIG. 5, phosphorus (P), serving as a donor, is ion-implanted into the silicon substrate 11, thereby forming ion-implanted regions 16A and 16B in the silicon substrate 11. Thereafter, the resist layer 17 is removed. Then, finally, the sample is heat-treated at about 900° C., activating the ion-implanted regions to form a source region 16A and a drain region 16B. In this way, the memory cell transistor of the first embodiment is formed.

A cross-section structure of an actually produced memory cell transistor was examined under a transmission electron microscope. As a result, it was confirmed that the film thickness of the silicon nitride layer (charge storage layer) 13 underlying the block insulating layer 14 and the film thickness of the tantalum nitride layer (control gate electrode) 15 on the block insulating layer 14 remained unchanged. That is, it may be said that neither the reaction of the block insulating layer 14 with the silicon nitride layer (charge storage layer) 13 nor the reaction of the block insulating layer 14 with the tantalum nitride layer (control gate electrode) 15 has occurred.

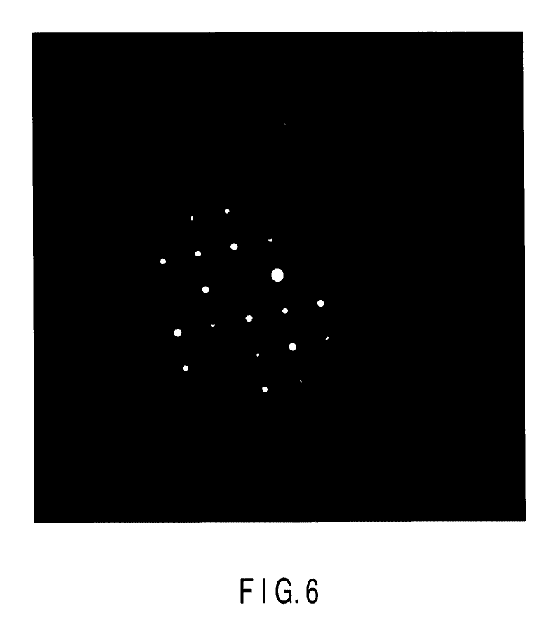

Furthermore, it was confirmed that the aluminum oxide layer 14A reacted with the lanthanum aluminate layer 14B, forming a crystallized single-layer lanthanum aluminate layer 14. The crystallization of the lanthanum aluminate layer (charge storage layer) 14 was confirmed using electron diffraction. FIG. 6 shows an electron diffraction image of the crystallized lanthanum aluminate layer (charge storage layer) 14.

Consequently, as shown in FIG. 1, a gate structure is formed in which the silicon oxide layer (tunnel insulating layer) 12, silicon nitride layer (charge storage layer) 13, single-layer lanthanum aluminate layer (block insulating layer) 14, and tantalum nitride layer (control gate electrode) 15 are stacked one on top of another in that order. Accordingly, it was confirmed that the source region 16A, drain region 16B, and crystallized single-layer lanthanum aluminate layer 14 were formed simultaneously by heat treatment at about 900° C.

Furthermore, using the gate structure including a (amorphous) lanthanum aluminate layer (LAO) before heat treatment and the gate structure including a (crystallized) lanthanum aluminate layer (LAO) after heat treatment, the current-voltage characteristic of each of the gate structures was measured. FIG. 7 is a diagram illustrating the percentage of leakage current Jg2 in the gate structure including a (crystallized) lanthanum aluminate layer (LAO) after heat treatment in a case where leakage current Jg1 in the gate structure including a (amorphous) lanthanum aluminate layer (LAO) before heat treatment is set at 100%.

As shown in FIG. 7, as compared with leakage current Jg1 (100%), leakage current Jg2 is about 13%. That is, the insulation quality of the lanthanum aluminate layer after heat treatment does not deteriorate as compared with that before heat treatment. From this, it is seen that the insulation quality has been improved. It is reported that the insulation quality of a crystallized insulating material is generally lower than that of an amorphous insulating material. However, it was confirmed that lanthanum aluminate became stable as a result of crystallization and therefore its insulation quality did not deteriorate.

With this manufacturing method, the composition ratio of aluminum to lanthanum in the single-layer lanthanum aluminate layer 14 can be controlled by adjusting the film thickness of the aluminum oxide layer 14A. To check the controllability of the composition ratio of aluminum to lanthanum, a gate structure where the film thickness of the aluminum oxide layer 14A was 15 nm and the film thickness of the lanthanum aluminate layer 14B whose composition ratio of aluminum to lanthanum was 1:1 was 5 nm was formed as the block insulating layer and subjected to heat treatment at about 900° C. As a result, a crystallized single-layer lanthanum aluminate 14 was formed.

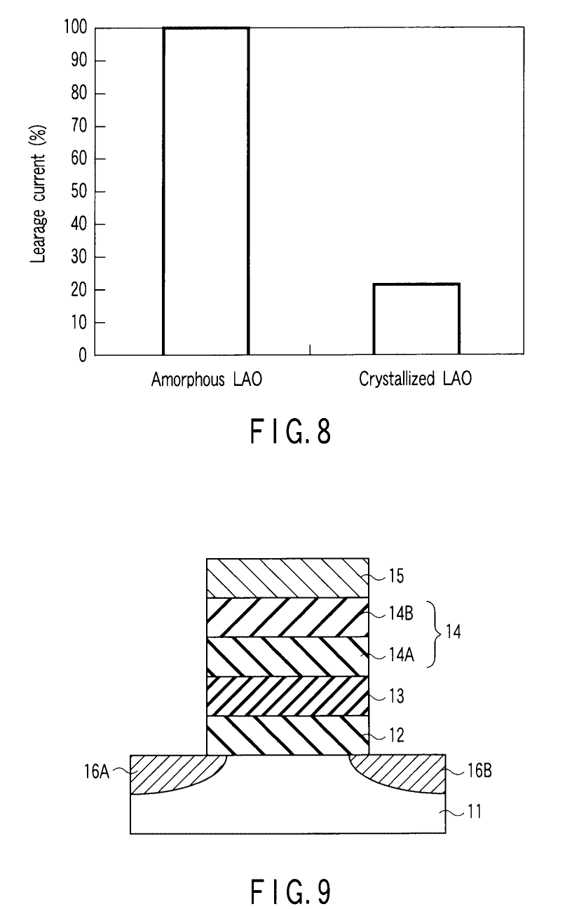

When the composition ratio of the crystallized single-layer lanthanum aluminate 14 was measured by ICP (Inductively Coupled Plasma) analysis, the lanthanum:aluminum ratio was 1:4. Comparison of the current-voltage characteristic of the gate structure before heat treatment with that after heat treatment (FIG. 8) has shown that the leakage characteristic of the (crystallized) lanthanum aluminate layer (LAO) after heat treatment has been improved. It was confirmed that an improvement in the leakage characteristic was found when the composition ratio of lanthanum (La) to aluminum (Al) was such that the Al content was not more than four times the La content.

On the other hand, if the ratio of lanthanum (La) to aluminum (Al) is too high, hygroscopicity and carbon absorption characteristics, which are the characteristics of lanthanum oxide, become pronounced, with the result that the lanthanum aluminate begins to absorb moisture and carbon dioxide gas. The lanthanum aluminate absorbs moisture and carbon dioxide gas, producing a mixed crystal of lanthanum aluminate and lanthanum hydrate or lanthanum carbonate. Since the relative permittivity of lanthanum hydrate or lanthanum carbonate is low, the overall relative permittivity decreases and the leakage characteristic deteriorates, degrading the characteristics of the memory cell transistor. Therefore, it is desirable that the composition ratio of lanthanum (La) to aluminum (Al) should be such that the Al content is equal to or larger than the La content.

As described in detail, in the first embodiment, a memory cell transistor is configured by using crystallized lanthanum aluminate (LAO: LaAlO₃) for the block insulating layer 14 arranged between the charge storage layer 13 and the control gate electrode 15.

Accordingly, with the first embodiment, even when the memory cell transistor is heat-treated, it is possible to prevent the reaction of the charge storage layer 13 with the block insulating layer 14 and the reaction of the control gate electrode 15 with the block insulating layer 14. This makes it possible to maintain the stacked structure of the charge storage layer 13, block insulating layer 14, and control gate electrode 15, with the result that the characteristics of the block insulating layer 14, charge storage layer 13, and control gate electrode 15 can be prevented from deteriorating.

Furthermore, since lanthanum aluminate is a high-dielectric material, the capacitance between the control gate electrode 15 and the charge storage layer 13 can be made higher. This makes it possible to improve the coupling ratio of the memory cell transistor, with the result that the operating voltage applied to the control gate electrode 15 can be decreased. That is, charge can be injected into or released from the charge storage layer 13 efficiently at a low voltage.

In addition, the lanthanum aluminate layer can be crystallized at the same time that heat treatment is performed at about 900° C. to activate the ion-implanted regions. This makes it possible to form a memory cell transistor of the first embodiment by the same number of heat treatment processes as in a conventional method of manufacturing memory cell transistors.

### Second Embodiment

The second embodiment suppresses the reaction of the charge storage layer with the lanthanum aluminate layer more by inserting stabilized aluminum oxide between the charge storage layer and the lanthanum aluminate layer as a part of the block insulating layer. FIG. 9 is a sectional view illustrating a memory cell transistor according to the second embodiment.

In a semiconductor substrate 11, a source region 16A and a drain region 16B are provided separately. On the semiconductor substrate 11 between the source region 16A and drain region 16B (that is, on the channel region), there is provided a gate structure in which a tunnel insulating layer 12, a charge storage layer 13, a block insulating layer 14, and a control gate 15 are stacked one on top of another in that order.

The block insulating layer 14 has a stacked structure in which an aluminum oxide layer 14A and a lanthanum aluminate layer 14B are stacked one on top of the other in that order. The lanthanum aluminate layer 14B is crystallized.

The lanthanum aluminate layer 14B becomes stable as a result of crystallization and its insulation quality deteriorates less than that of amorphous lanthanum aluminate. Use of the crystallized lanthanum aluminate layer 14B as a part of the block insulating layer 14 prevents the layer 14 from reacting with the control gate electrode 15.

Moreover, the aluminum oxide layer 14A is inserted between the charge storage layer 13 and the lanthanum aluminate layer 14B. This suppresses the reaction of the lanthanum aluminate layer 14B with the charge storage layer 13. As a result, it is possible to prevent the characteristics of the lanthanum aluminate layer 14B, charge storage layer 13, and control gate electrode 15 from deteriorating.

Since lanthanum aluminate (LAO) is a high-dielectric material, the capacitance between the control gate electrode 15 and the charge storage layer 13 can be made higher. This improves the coupling ratio of the memory cell transistor, which enables the operating voltage applied to the control gate electrode 15 to be decreased.

Next, referring to the accompanying drawings, a method of manufacturing a memory cell transistor of the second embodiment will be explained.

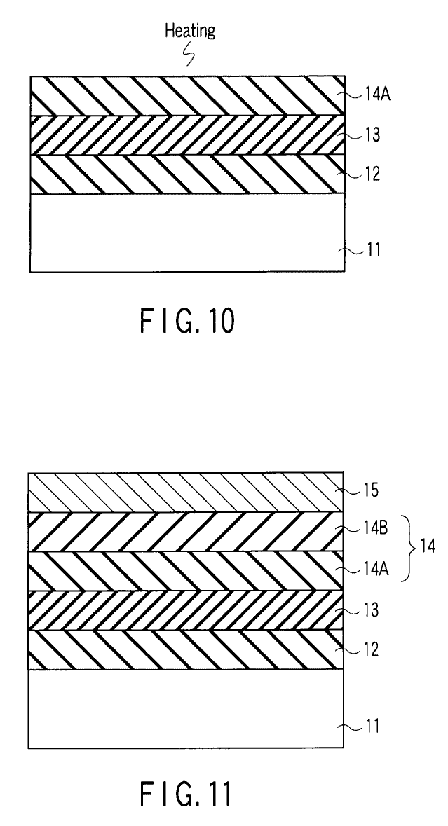

As shown in FIG. 10, on a p-type silicon substrate 11, a silicon oxynitride layer 12 with a film thickness of about 5 nm is formed as a tunnel insulating layer using, for example, CVD method. Then, on the silicon oxynitride layer 12, a hafnium oxynitride layer 13 with a film thickness of about 5 nm is formed as a charge storage layer using, for example, CVD method.

Next, on the hafnium oxynitride layer 13, an aluminum oxide layer 14A with a film thickness of about 5 nm is formed as a part of the block insulating layer by, for example, CVD method. Then, the sample is heat-treated at about 900° C., thereby stabilizing the aluminum oxide layer 14A.

Next, as shown in FIG. 11, on the stabilized aluminum oxide layer 14A, a lanthanum aluminate layer 14B with a film thickness of about 10 nm is formed using, for example, MBE method. Then, on the lanthanum aluminate layer 14B, a tantalum carbide layer 15 with a film thickness of about 5 nm is formed as a control gate electrode using, for example, sputtering method.

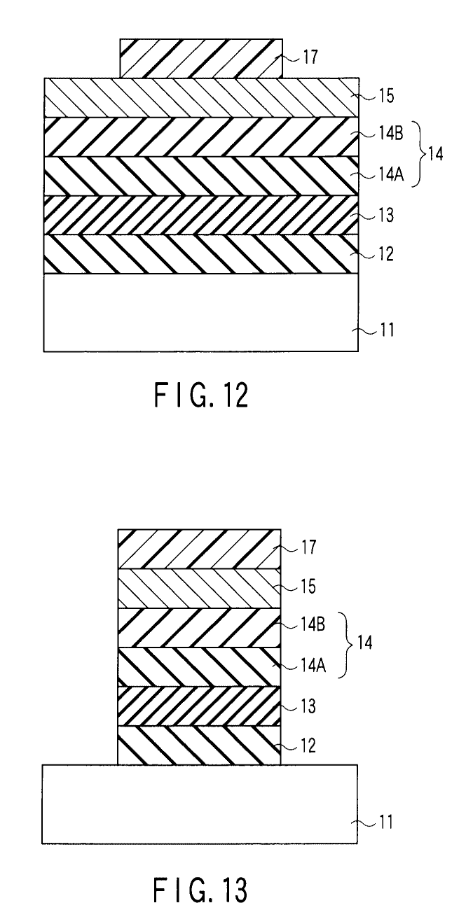

Next, as shown in FIG. 12, to form a gate structure having a desired planar shape, a resist layer 17 is formed on the tantalum carbide layer 15 using lithographic method. Then, as shown in FIG. 13, with the resist layer 17 as a mask, the gate structure is etched using RIE method, thereby exposing the top surface of the silicon substrate 11.

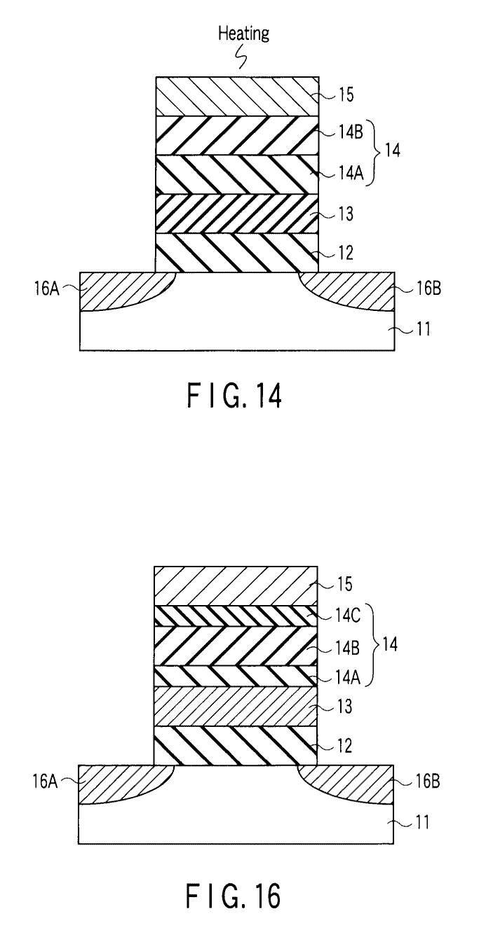

Next, as shown in FIG. 14, phosphorus (P), serving as a donor, is ion-implanted into the silicon substrate 11, thereby forming ion-implanted regions 16A and 16B in the silicon substrate 11. Thereafter, the resist layer 17 is removed. Then, finally, the sample is heat-treated at about 900° C., activating the ion-implanted regions to form a source region 16A and a drain region 16B. In the heat treatment process, the lanthanum aluminate layer 14B is crystallized. In this way, the memory cell transistor of the second embodiment is formed.

In the first embodiment, after the aluminum oxide layer 14A and lanthanum aluminate layer 14B are stacked one on top of the other in that order as the block insulating layer, the aluminum oxide layer 14A and lanthanum aluminate layer 14B are mixed when heat treatment is performed to activate the ion-implanted regions, thereby forming the crystallized single-layer lanthanum aluminate layer 14. However, if the aluminum oxide layer 14A is made too thin, the charge storage layer 13 and lanthanum aluminate layer 14 might react with each other. Therefore, the film thickness of the aluminum oxide 14A might have to be controlled.

However, in the second embodiment, after the aluminum oxide layer 14A is formed on the charge storage layer 13, heat treatment is performed at about 900° C., thereby stabilizing the aluminum oxide layer 14A. Then, a lanthanum aluminate layer 14B is formed on the stabilized aluminum oxide layer 14A, thereby suppressing the reaction of the hafnium oxynitride layer 13 as the charge storage layer with the lanthanum aluminate layer 14B.

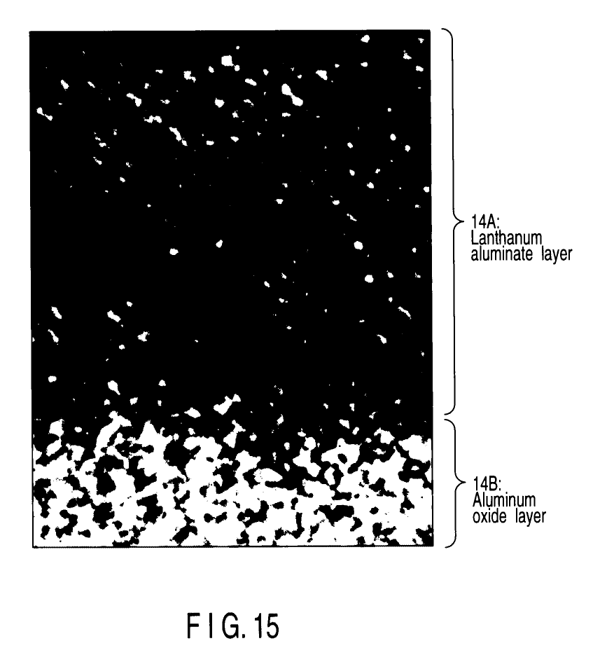

A cross-section structure of a memory cell transistor actually produced in the second embodiment was examined under a transmission electron microscope. As a result, it was confirmed that the aluminum oxide layer 14 and lanthanum aluminate layer 14B maintained the stacked structure (FIG. 15). Moreover, as in the first embodiment, the crystallization of the lanthanum aluminate layer 14B was confirmed on the basis of an electron diffraction image.

Consequently, as shown in FIG. 9, a gate structure where the silicon oxynitride layer 12, hafnium oxynitride layer 13, aluminum oxide layer 14A, lanthanum aluminate layer 14B, tantalum carbide layer 15 are stacked one on top of another in that order can be maintained after the heat treatment for activating the ion-implanted regions 16A and 16B. That is, since the reaction of the layers constituting the gate structure can be suppressed, the characteristics of the individual layers can be prevented from deteriorating.

Furthermore, as in the first embodiment, the comparison of the current-voltage characteristic of the gate structure of the second embodiment before heat treatment with that after heat treatment has shown that the leakage characteristic of the (crystallized) lanthanum aluminate layer 14B after heat treatment has been improved. Moreover, it was confirmed that the improvement in the leakage characteristic of the lanthanum aluminate layer 14B was found when the composition ratio of lanthanum (La) to aluminum (Al) was such that the Al content was not less than 1 and 4 or less if La is 1.

### Third Embodiment

The third embodiment suppresses the reaction of the charge storage layer with the lanthanum aluminate layer more by inserting stabilized aluminum oxide between the charge storage layer and a lanthanum aluminate layer as a part of the block insulating layer. Moreover, the third embodiment suppresses the reaction of the control gate electrode with the lanthanum aluminate layer more by the insertion of stabilized aluminum oxide between the control gate electrode and the lanthanum aluminate layer. FIG. 16 is a sectional view illustrating a memory cell transistor according to the third embodiment.

In a semiconductor substrate 11, a source region 16A and a drain region 16B are provided separately. On the semiconductor substrate 11 between the source region 16A and drain region 16B (that is, on the channel region), there is provided a gate structure in which a tunnel insulating layer 12, a charge storage layer 13, a block insulating layer 14, and a control gate 15 are stacked one on top of another in that order.

The block insulating layer 14 has a stacked structure in which an aluminum oxide layer 14A, a lanthanum aluminate layer 14B, and an aluminum oxide layer 14C are stacked one on top of another in that order. The lanthanum aluminate layer 14B is crystallized.

That is, the aluminum oxide layer 14A is inserted between the charge storage layer 13 and the lanthanum aluminate layer 14B. The aluminum oxide layer 14C is inserted between the lanthanum aluminate layer 14B and the control gate electrode 15. The lanthanum aluminate layer 14B is crystallized. As a result, the reaction of the lanthanum aluminate layer 14B with the charge storage layer 13 can be suppressed. Moreover, the reaction of the lanthanum aluminate layer 14B with the control gate electrode 15 can be suppressed. As a result, the characteristics of the lanthanum aluminate layer 14B, charge storage layer 13, and control gate electrode 15 can be prevented from deteriorating.

Since lanthanum aluminate (LAO) is a high-dielectric material, the capacitance between the control gate 15 and the charge storage layer 13 can be made higher. This improves the coupling ratio of the memory cell transistor, which enables the operating voltage applied to the control gate electrode 15 to decrease.

Next, referring to the accompanying drawings, a method of manufacturing a memory cell transistor of the third embodiment will be explained.

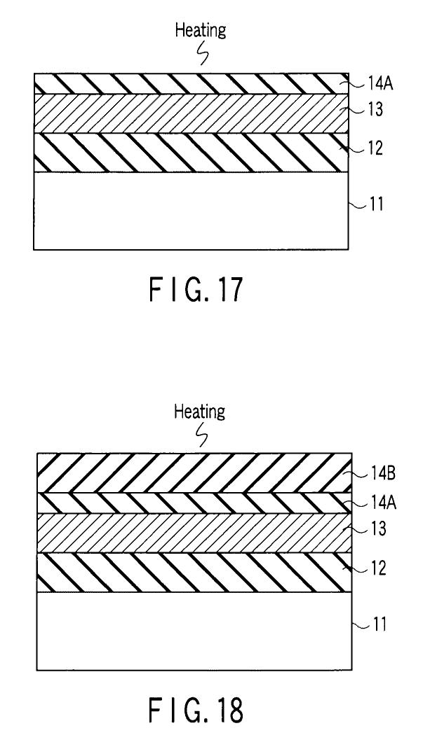

As shown in FIG. 17, on a p-type silicon substrate 11, a silicon oxynitride layer 12 with a film thickness of about 5 nm is formed as a tunnel insulating layer using, for example, CVD method. Then, on the silicon oxynitride layer 12, a polysilicon layer 13 with a film thickness of about 5 nm is formed as a charge storage layer using, for example, CVD method.

Next, on the polysilicon layer 13, an aluminum oxide layer 14A with a film thickness of about 5 nm is formed as a part of the block insulating layer using, for example, MBE method. Then, the sample is heat-treated at about 900° C., thereby stabilizing the aluminum oxide layer 14A.

Next, as shown in FIG. 18, on the stabilized aluminum oxide layer 14A, a lanthanum aluminate layer 14B with a film thickness of about 10 nm is formed using, for example, MBE method. Then, the sample is heat-treated at about 900° C., thereby stabilizing the lanthanum aluminate layer 14B.

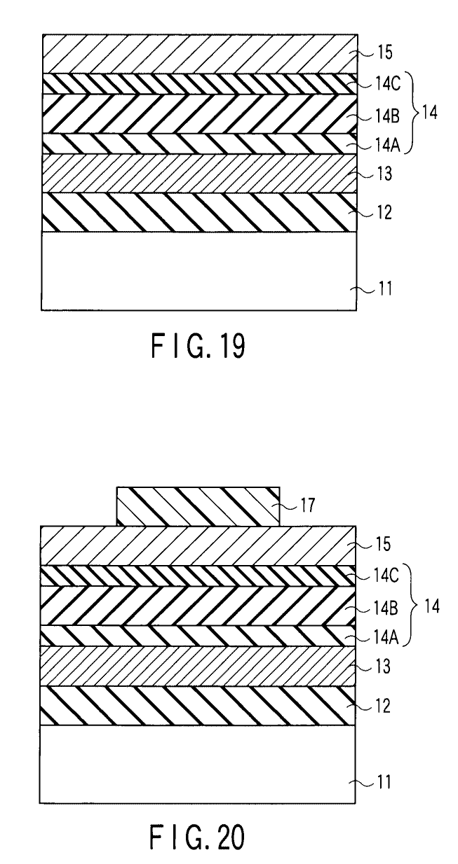

Next, as shown in FIG. 19, on the crystallized lanthanum aluminate layer 14B, an aluminum oxide layer 14C with a film thickness of about 5 nm is formed as a part of the block insulating layer using, for example, MBE method. Then, on the aluminum oxide layer 14C, a polysilicon layer 15 with a film thickness of about 5 nm is formed as a control gate electrode using, for example, CVD method.

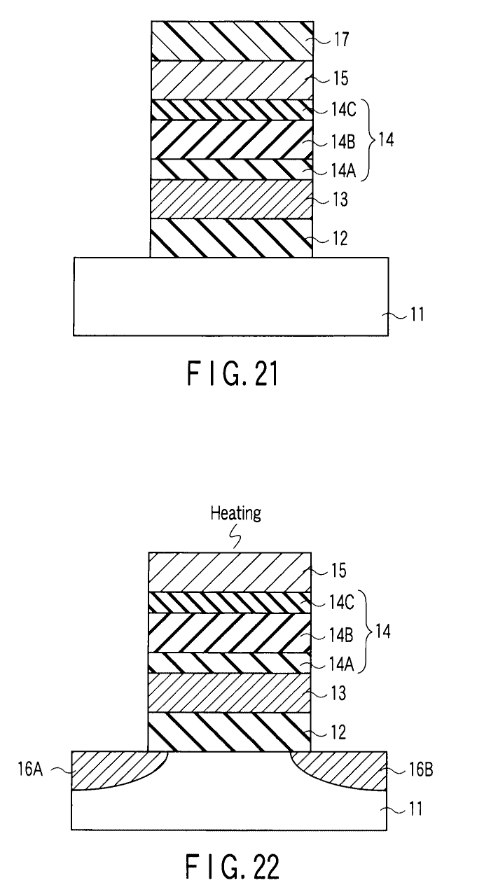

Next, as shown in FIG. 20, to form a gate structure having a desired planar shape, a resist layer 17 is formed on the polysilicon layer 15 using lithographic method. Then, as shown in FIG. 21, with the resist layer 17 as a mask, the gate structure is etched using RIE method, thereby exposing the top surface of the silicon substrate 11.

Next, as shown in FIG. 22, phosphorus (P), serving as a donor, is ion-implanted into the silicon substrate 11, thereby forming ion-implanted regions 16A and 16B in the silicon substrate 11. Thereafter, the resist layer 17 is removed. Then, finally, the sample is heat-treated at about 900° C., activating the ion-implanted regions to form a source region 16A and a drain region 16B. In this way, the memory cell transistor of the second embodiment is formed.

As described above in detail, in the third embodiment, after the aluminum oxide layer 14A is formed on the charge storage layer 13, heat treatment is performed at about 900° C., thereby stabilizing the aluminum oxide layer 14A. Then, a lanthanum aluminate layer 14B is formed on the aluminum oxide layer 14A, thereby suppressing the reaction of the polysilicon layer 13 as the charge storage layer with the lanthanum aluminate layer 14B.

Furthermore, after the lanthanum aluminate layer 14B is formed on the aluminum oxide 14A, heat treatment is performed at about 900° C., thereby stabilizing the lanthanum aluminate layer 14B. Then, after an aluminum oxide layer 14C and a polysilicon layer 15 are formed in that order on the lanthanum aluminate layer 14B, heat treatment is performed to activate the ion-implanted regions. This suppresses the reaction of the polysilicon layer 15 as the control gate electrode with the lanthanum aluminate layer 14B.

A cross-section structure of a memory cell transistor actually produced in the third embodiment was examined under a transmission electron microscope. As a result, it was confirmed that the aluminum oxide layer 14A, lanthanum aluminate layer 14B, and aluminum oxide layer 14C maintained the stacked structure. Moreover, as in the first embodiment, the crystallization of the lanthanum aluminate layer 14B was confirmed from an electron diffraction image.

Consequently, as shown in FIG. 16, the gate structure where the silicon oxynitride layer 12, polysilicon layer 13, aluminum oxide layer 14A, lanthanum aluminate layer 14B, aluminum oxide layer 14C, and polysilicon layer 15 are stacked one on top of another in that order can be maintained even after the heat treatment for activating the ion-implanted regions 16A and 16B. That is, since the reaction of the layers constituting the gate structure can be suppressed, the characteristics of the individual layers can be prevented from deteriorating.

Furthermore, as in the first embodiment, the comparison of the current-voltage characteristic of the gate structure of the third embodiment before heat treatment with that after heat treatment has shown that the leakage characteristic of the crystallized lanthanum aluminate layer 14B after heat treatment has been improved. Moreover, it was confirmed that the improvement in the leakage characteristic of the lanthanum aluminate layer 14B was found when the composition ratio of lanthanum (La) to aluminum (Al) was such that the Al content was not less than 1 and 4 or less if La is 1.

### Fourth Embodiment

After the memory cell transistor shown in each of the first to third embodiments is formed, the process of filling an interlayer insulating layer in a space between elements is generally carried out. Usually, silicon oxide is used for an interlayer insulating layer. Since lanthanum in lanthanum aluminate is liable to diffuse at high temperature, use of silicon oxide for the interlayer insulating layer might permit lanthanum to diffuse into the silicon oxide layer. As a result, not only do the characteristics of the lanthanum aluminate layer deteriorate, but also the permittivity of the interlayer insulating layer becomes higher, with the result that the characteristics of the memory cell transistor deteriorate.

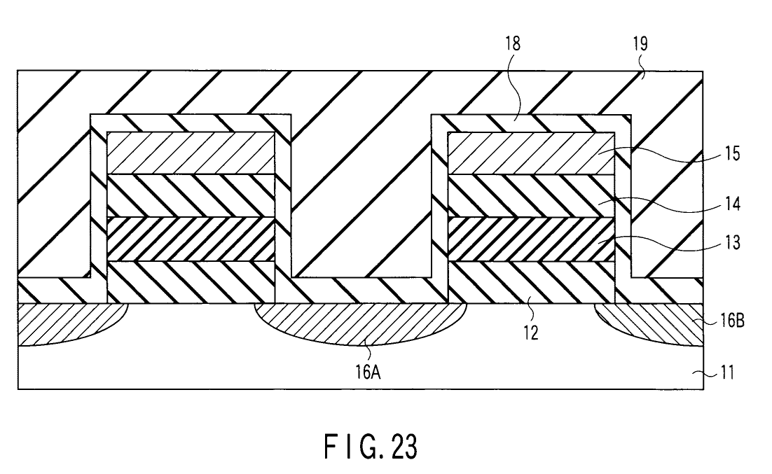

To overcome this problem, an interlayer insulating layer is formed after the memory cell transistor is covered with an aluminum oxide layer in the fourth embodiment. FIG. 23 is a sectional view illustrating a memory cell transistor according to the fourth embodiment.

The gate structure is the same as, for example, in the first embodiment. On a semiconductor substrate 11, an aluminum oxide film 18 with a film thickness of about 2 nm is provided so as to cover the gate structure. The aluminum oxide film 18 functions as a part of an interlayer insulating layer. On the aluminum oxide film 18, an interlayer insulating layer 19 is provided so as to fill the space between adjacent memory cell transistors. For example, silicon oxide is used for the interlayer insulating layer 19.

In the memory cell transistor configured as described above, the aluminum oxide film 18 functions as a barrier film to cover the crystallized lanthanum aluminate layer 14 serving as the block insulating layer. The aluminum oxide film 18 prevents lanthanum included in the lanthanum aluminate layer 14 from diffusing into the interlayer insulating layer 19.

The fourth embodiment can naturally be applied to the second and third embodiments. Specifically, when the third embodiment is applied to the second embodiment, a memory cell transistor is so configured that the bottom surface of the lanthanum aluminate layer 14B is covered with the aluminum oxide layer 14A and both of the side faces of the lanthanum aluminate layer 14B are covered with the aluminum oxide film 18.

Furthermore, when the fourth embodiment is applied to the third embodiment, the top surface and bottom surface of the lanthanum aluminate layer 14B are covered with the aluminum oxide layer 14A and aluminum oxide layer 14C, respectively. Moreover, both of the side faces of the lanthanum aluminate layer 14B are covered with the aluminum oxide film 18. In other words, a memory cell transistor obtained by applying the fourth embodiment to the third embodiment is so configured that all of the surfaces of the lanthanum aluminate layer 14B are covered with an aluminum oxide layer.

### COMPARATIVE EXAMPLE

Hereinafter, a comparative example of the memory cell transistor shown in the first embodiment will be explained.

On a p-type silicon substrate 11, a silicon oxide layer 12 with a film thickness of about 5 nm is formed as a tunnel insulating layer using, for example, a thermal oxidation method. Then, on the silicon oxide layer 12, a silicon nitride layer 13 with a film thickness of about 5 nm is formed as a charge storage layer using, for example, CVD method.

Next, on the silicon nitride layer 13, a lanthanum aluminate layer 14 with a film thickness of about 15 nm is formed as a block insulating layer using, for example, MBE method. Then, on the lanthanum aluminate layer 14, a tantalum nitride layer 15 with a film thickness of about 5 nm is formed as a control gate electrode using, for example, sputtering method.

In the lanthanum aluminate layer 14, a lanthanum (La) to aluminum (Al) composition ratio of Al/La is set to 4.1.

Then, the sample was heat-treated at about 900° C. in an atmosphere of nitrogen in expectation of heat treatment for activating the ion-implanted regions. In the heat treatment process, the amorphous state of the lanthanum aluminate layer 14 is maintained.

When a sample whose gate structured is the same as described above and in which the Al/La composition ratio of the lanthanum aluminate layer 14 is 4.1 is heat-treated at about 1000° C., not at about 900° C., in an atmosphere of nitrogen, the lanthanum aluminate layer 14 is crystallized. The current-voltage characteristic of a sample obtained by crystallizing the lanthanum aluminate layer 14 by the heat treatment at about 1000° C. and that of a sample obtained by maintaining the lanthanum aluminate layer 14 in the amorphous state by heat treatment at about 900° C. were measured. As a result, it was confirmed that the leakage current in the crystallized lanthanum aluminate layer was reduced to about 1/10 of the leakage current in the amorphous lanthanum aluminate layer.

Furthermore, when the same gate structure where the Al/La composition ratio of the lanthanum aluminate layer 14 was set to 4 was produced and the sample was heat-treated at about 900° C. in an atmosphere of nitrogen, it was confirmed that the lanthanum aluminate layer 14 was crystallized. That is, when the Al/La composition ratio of aluminum to lanthanum is set to 4.1 or more, the crystallization of the lanthanum aluminate layer 14 requires heat treatment at a temperature higher than 900° C., which makes it difficult to carry out processes at lower temperatures.

Accordingly, from the viewpoint of lower-temperature processing, it is desirable that the Al/La composition ratio of the lanthanum aluminate layer 14 be 4 or less.

The invention is not limited to the method of forming the tunnel insulating layer, charge storage layer, block insulating layer, and control gate electrode shown in each of the first to third embodiments. For instance, various types of methods, including the MBE method, sputtering method, CVD method, ALD (Atomic Layer Deposition) method, thermal vapor deposition method, electron beam vapor deposition method, and laser abrasion method, and combinations of these methods, can be used. The effect of each of the embodiments can be obtained, regardless of the type of film forming method.

Furthermore, while a silicon substrate has been used as an example of the semiconductor substrate, the invention may be applied to any type of semiconductor substrate and transistor structure, such as an SOI substrate, a polysilicon substrate, or a fin-type substrate. In addition, the memory cell transistor of the invention may be applied to a NAND, a NOR, an AND, a DINOR (Divided bit-line NOR), a NANO, or an ORNAND memory cell array.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory element comprising:
a semiconductor substrate;
a source region and a drain region which are provided separately in the semiconductor substrate;
a tunnel insulating layer which is provided between the source region and the drain region on the semiconductor substrate;
a charge storage layer which is provided on the tunnel insulating layer;
a block insulating layer which is provided on the charge storage layer and includes a crystallized lanthanum aluminate layer; and
a control gate electrode which is provided on the block insulating layer.

2. The element according to claim 1, wherein the block insulating layer includes an aluminum oxide layer provided between the charge storage layer and the lanthanum aluminate layer.

3. The element according to claim 1, wherein the block insulating layer further includes an aluminum oxide layer provided between the lanthanum aluminate layer and the control gate electrode.

4. The element according to claim 1, wherein the block insulating layer further includes:
a first aluminum oxide layer provided between the charge storage layer and the lanthanum aluminate layer; and
a second aluminum oxide layer provided between the lanthanum aluminate layer and the control gate electrode.

5. The element according to claim 1, wherein the block insulating layer further includes an aluminum oxide layer which covers the lanthanum aluminate layer.

6. The element according to claim 1, wherein the lanthanum aluminate layer has an aluminum (Al) to lanthanum (La) composition ratio of Al/La which satisfies the expression 1≦Al/La≦4.

7. The element according to claim 1, wherein the tunnel insulating layer contains silicon oxide, silicon nitride, or silicon oxynitride.

8. The element according to claim 1, wherein the charge storage layer contains an oxide or oxynitride which includes at least one of silicon (Si), aluminum (Al), titanium (Ti), zirconium (Zr), and hafnium (Hf).

9. The element according to claim 1, wherein the charge storage layer contains a conductive material.

10. The element according to claim 9, wherein the conductive material is polysilicon or a metal.

11. The element according to claim 1, wherein the control gate electrode contains polysilicon or a metal.

12. A method of manufacturing a nonvolatile semiconductor memory element, comprising:
forming a tunnel insulating layer on a semiconductor substrate;
forming a charge storage layer on the tunnel insulating layer;
forming, on the charge storage layer, a block insulating layer including a lanthanum aluminate layer;
forming a control gate electrode on the block insulating layer;
introducing impurities in the semiconductor substrate to form a first impurity region and a second impurity region in the semiconductor substrate; and
performing a heat treatment to crystallize the lanthanum aluminate layer.

13. The method according to claim 12, wherein the heat treatment is performed to activate the first impurity region and the second impurity region.

14. The method according to claim 12, wherein the step of forming the block insulating layer includes:
forming an aluminum oxide layer on the charge storage layer;
heating the aluminum oxide layer; and
forming the lanthanum aluminate layer on the aluminum oxide layer after heating the aluminum oxide layer.

15. The method according to claim 12, wherein the step of forming the block insulating layer includes:
forming a first aluminum oxide layer on the charge storage layer;
heating the first aluminum oxide layer;
forming the lanthanum aluminate layer on the first aluminum oxide layer after heating the first aluminum oxide layer; and
forming a second aluminum oxide layer on the lanthanum aluminate layer.

16. The method according to claim 12, wherein the lanthanum aluminate layer has an aluminum (Al) to lanthanum (La) composition ratio of Al/La which satisfies the expression 1≦Al/La≦4.

17. The method according to claim 12, wherein the tunnel insulating layer contains silicon oxide, silicon nitride, or silicon oxynitride.

18. The method according to claim 12, wherein the charge storage layer contains an oxide or oxynitride which includes at least one of silicon (Si), aluminum (Al), titanium (Ti), zirconium (Zr), and hafnium (Hf).

19. The method according to claim 12, wherein the charge storage layer contains a conductive material.

20. The method according to claim 19, wherein the conductive material is polysilicon or a metal.
